(19) United States
(12) Patent Application Publication
(10) Pub. No.: US 2008/0064142 A1
(43) Pub. Date: Mar. 13, 2008

(54) Method for fabricating a wafer level package having through wafer vias for external package connectivity

(75) Inventors: QING GAN, Fremont, CA (US); ANTHONY LOBIANCO, Irvine, CA (US); ROBERT W. WARREN, Newport Beach, CA (US)

Correspondence Address: Michael Farjami, Esq.;FARJAMI & FARJAMI LLP, 26522 La Alameda Ave., Suite 360, Mission Viejo, CA, 92691, US

(73) Assignee: Skyworks Solutions, Inc.

(21) Appl. No.: 11/978,026

(22) Filed: Oct. 26, 2007

Related U.S. Application Data
(62) Division of application No. 11/085,968, filed on Mar. 21, 2005.

(51) Int. Cl. H01L 21/98

(52) U.S. Cl. 438/118; 257/E21.705

(57) ABSTRACT

According to an exemplary embodiment, a method for fabricating a wafer level package includes forming a polymer layer on a device wafer, where the device wafer includes at least one device wafer contact pad and a device, and where the at least one device wafer contact pad is electrically connected to the device. The method further includes bonding a protective wafer to the device wafer. The method further includes forming at least one via in the protective wafer, where the at least one via extends through the protective wafer and is situated over the at least one device wafer contact pad. The method further includes forming at least one protective wafer contact pad on the protective wafer, where the at least one protective wafer contact pad is situated over the at least one via and electrically connected to the at least one device wafer contact pad.

### BACKGROUND OF THE INVENTION

1. Field of the Invention

The present invention is generally in the field of semiconductors. More particularly, the invention is in the field of wafer level packaging.

2. Background Art

Electronic devices, such as cellular phones and personal digital assistants (PDAs), continue to decrease in size and price and increase in functionality. As a result, these electronic devices require smaller, lower cost components, such as integrated circuits (ICs) and Micro-Electro-Mechanical Systems (MEMS) devices. However, packaging generally consumes between approximately 40.0 percent and approximately 90.0 percent of the total manufacturing cost of the ICs and MEMS devices. As a result, wafer level packaging has emerged as a leading solution to the challenge of providing low cost IC and MEMS device packages that also have a reduced footprint.

By way of background, in wafer level packaging, and specially for devices requiring cavities thereover, a layer of bonding material may be used to bond a protective wafer to a device wafer, which may include ICs or MEMS devices. In one conventional wafer level packaging process, frit glass compound is screen printed, spun coated, or deposited to form a bonding layer pattern. However, during the bonding process at a high temperature, molten glass run out can damage active areas of devices on the wafer. To adequately protect the devices from the molten glass run out, a large amount of space must be provide between the bonding layer pattern and devices, which undesirably increases the size of the resulting wafer level package.

In another conventional wafer level packaging process, a thin metal layer such as gold, gold-based alloys, copper, copper-based alloys, or solders are used to form a bonding layer. Although this approach provides a hermetically sealed wafer level package, the use of the metal bonding layer undesirably increases manufacturing cost, especially for those applications that do not require a hermetically sealed package.

In a conventional process for providing a non-hermetic wafer level package, a polymer is used as a bonding layer to bind two wafers together and an electrical feedthrough underneath the polymer is used to connect devices encircled by the polymer seal ring to contact pads situated outside of the wafer level package. These contact pads are used for wire bonding to electrically connect to other devices. Although this conventional packaging process provides a relatively low cost package, the wire-bonding consumes an undesirable amount of space in the next level package.

Thus, there is a need in the art for a packaging process that achieves a wafer level package having a low cost and a desirably small footprint.

### SUMMARY OF THE INVENTION

The present invention is directed to method for fabricating a wafer level package having through wafer vias for external package connectivity and related structure. The present invention addresses and resolves the need in the art for a packaging process that achieves a wafer level package having a low cost and a desirably small footprint.

According to an exemplary embodiment, a method for fabricating a wafer level package includes forming a polymer layer on a device wafer, where the device wafer includes at least one device wafer contact pad and at least one device, and where the at least one device wafer contact pad is electrically connected to the at least one device. For example, the polymer layer may include a photoimageable polymer. The method further includes forming at least one opening and a seal ring in the polymer layer, where the at least one opening is situated over the at least one device wafer contact pad and the seal ring surrounds the device. The method further includes bonding a protective wafer to the device wafer. At least one cavity may be formed in the protective wafer prior to bonding the protective wafer to the device wafer, for example.

According to this exemplary embodiment, the method further includes performing a thinning process to achieve a target thickness of the protective wafer. The method further includes forming at least one via in the protective wafer, where the at least one via extends through the protective wafer, and where the at least one via is situated over the at least one device wafer contact pad. The at least one via may have a diameter of between approximately 10.0 microns and approximately 100.0 microns, for example. The at least one via can be filled with a conductive layer, where the conductive layer is in contact with the at least one device wafer contact pad. The method further includes forming at least one protective wafer contact pad on the protective wafer, where the at least one protective wafer contact pad is situated over the at least one via and electrically connected to the at least one device wafer contact pad. The method may further include forming at least one solder bump on the at least one protective wafer contact pad. The method further includes performing a thinning process to achieve a target thickness of the device wafer.

According to one embodiment, the invention is a structure that is achieved by utilizing the above-described method. Other features and advantages of the present invention will become more readily apparent to those of ordinary skill in the art after reviewing the following detailed description and accompanying drawings.

### BRIEF DESCRIPTION OF THE DRAWINGS

FIG. 1 shows a flowchart illustrating the steps taken to implement an embodiment of the present invention.

FIG. 2A illustrates a cross-sectional view, which includes a portion of a wafer processed according to an embodiment of the invention, corresponding to an initial step in the flowchart in FIG. 1.

FIG. 2B illustrates a cross-sectional view, which includes a portion of a wafer processed according to an embodiment of the invention, corresponding to an intermediate step in the flowchart in FIG. 1.

FIG. 2C illustrates a cross-sectional view, which includes a portion of a wafer processed according to an embodiment of the invention, corresponding to an intermediate step in the flowchart in FIG. 1.

FIG. 2D illustrates a cross-sectional view, which includes a portion of a wafer processed according to an embodiment of the invention, corresponding to an intermediate step in the flowchart in FIG. 1.

FIG. 2E illustrates a cross-sectional view, which includes a portion of a wafer processed according to an embodiment of the invention, corresponding to an intermediate step in the flowchart in FIG. 1.

FIG. 2F illustrates a cross-sectional view, which includes a portion of a wafer processed according to an embodiment of the invention, corresponding to a final step in the flowchart in FIG. 1.

### DETAILED DESCRIPTION OF THE INVENTION

The present invention is directed to method for fabricating a wafer level package having through wafer vias for external package connectivity and related structure. The following description contains specific information pertaining to the implementation of the present invention. One skilled in the art will recognize that the present invention may be implemented in a manner different from that specifically discussed in the present application. Moreover, some of the specific details of the invention are not discussed in order to not obscure the invention. The specific details not described in the present application are within the knowledge of a person of ordinary skill in the art.

The drawings in the present application and their accompanying detailed description are directed to merely exemplary embodiments of the invention. To maintain brevity, other embodiments of the invention which use the principles of the present invention are not specifically described in the present application and are not specifically illustrated by the present drawings.

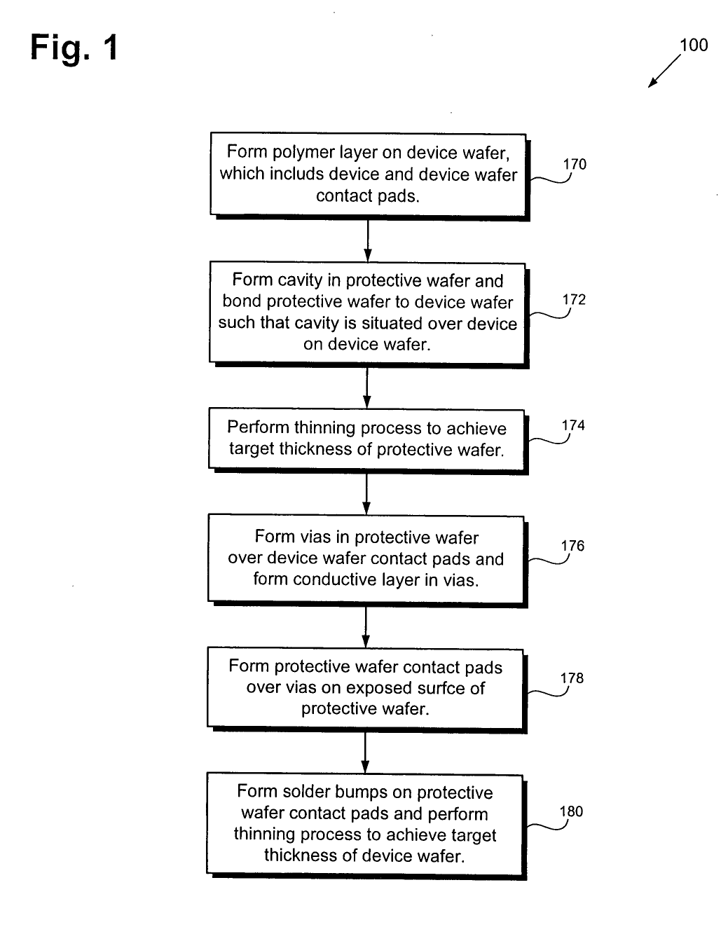

FIG. 1 shows a flow chart illustrating an exemplary method according to an embodiment of the present invention. Certain details and features have been left out of flowchart 100 that are apparent to a person of ordinary skill in the art. For example, a step may consist of one or more substeps or may involve specialized equipment or materials, as known in the art. Steps 170 through 180 indicated in flowchart 100 are sufficient to describe one embodiment of the present invention; other embodiments of the invention may utilize steps different from those shown in flowchart 100.

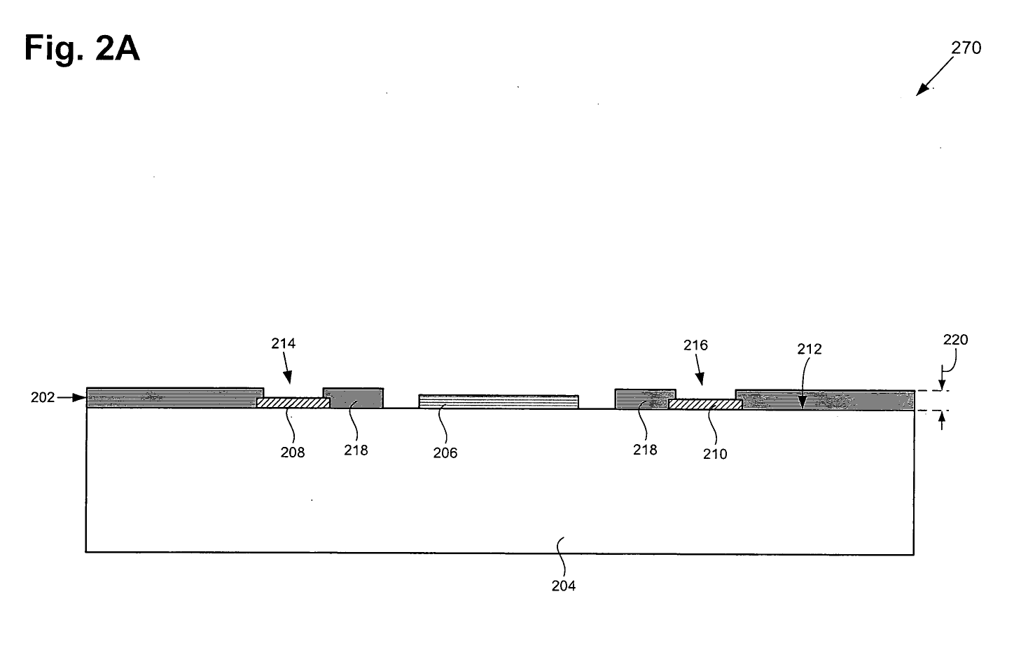

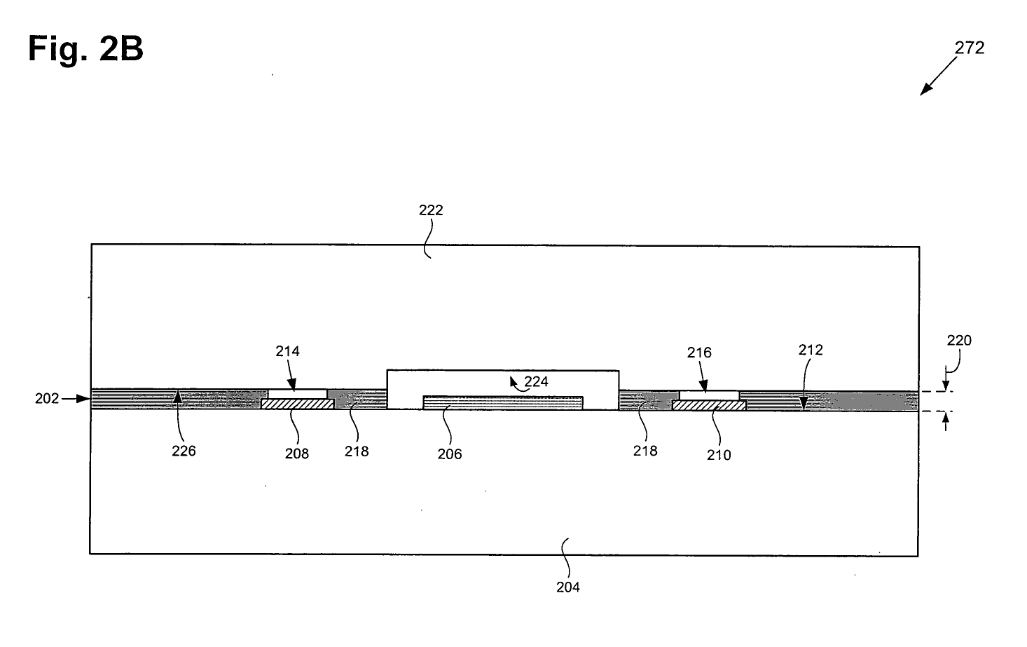

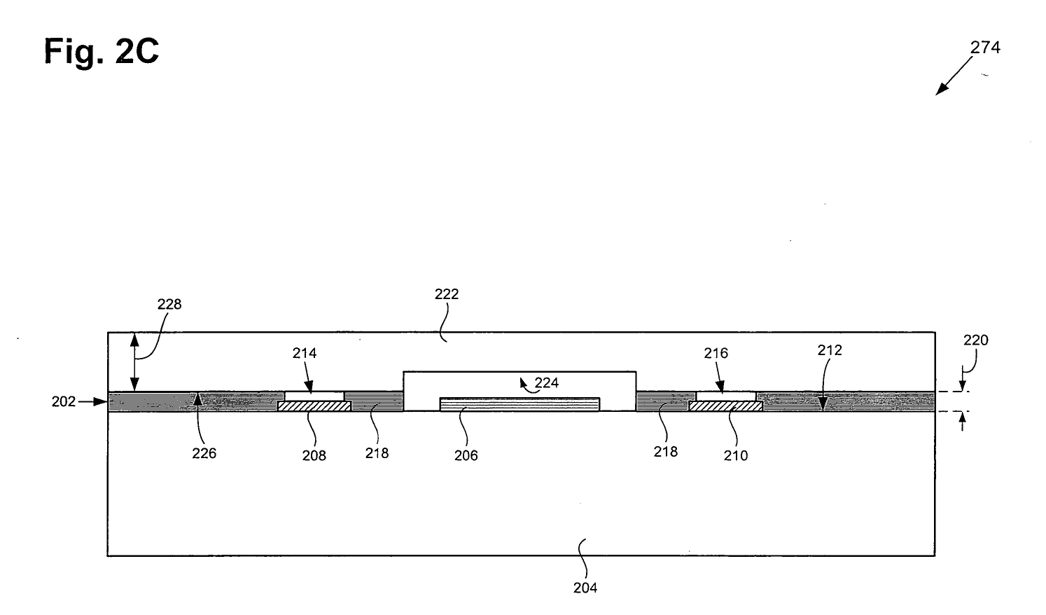

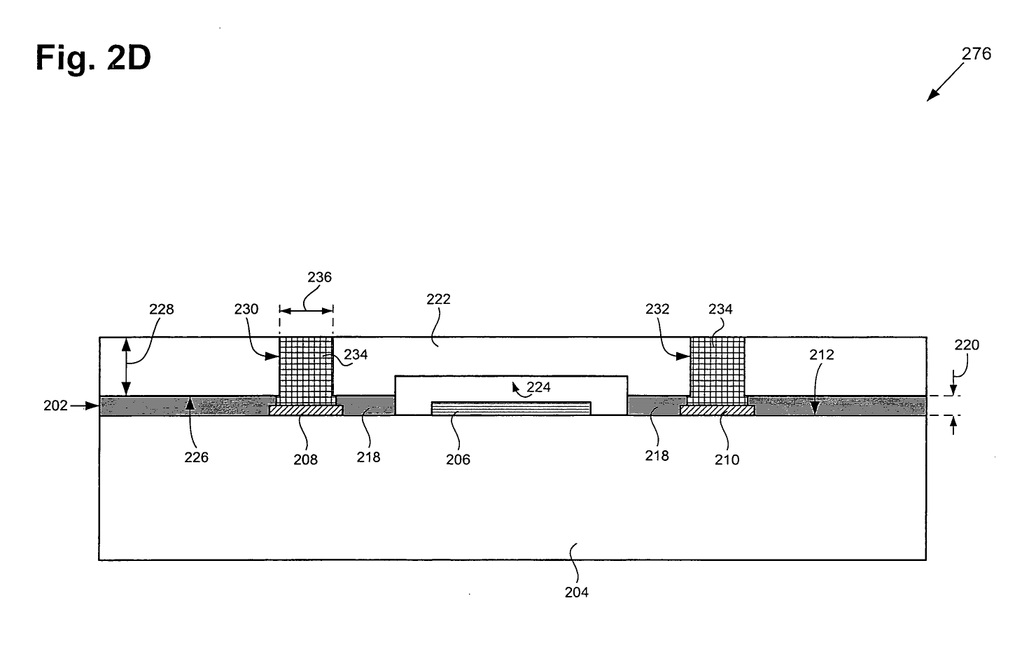

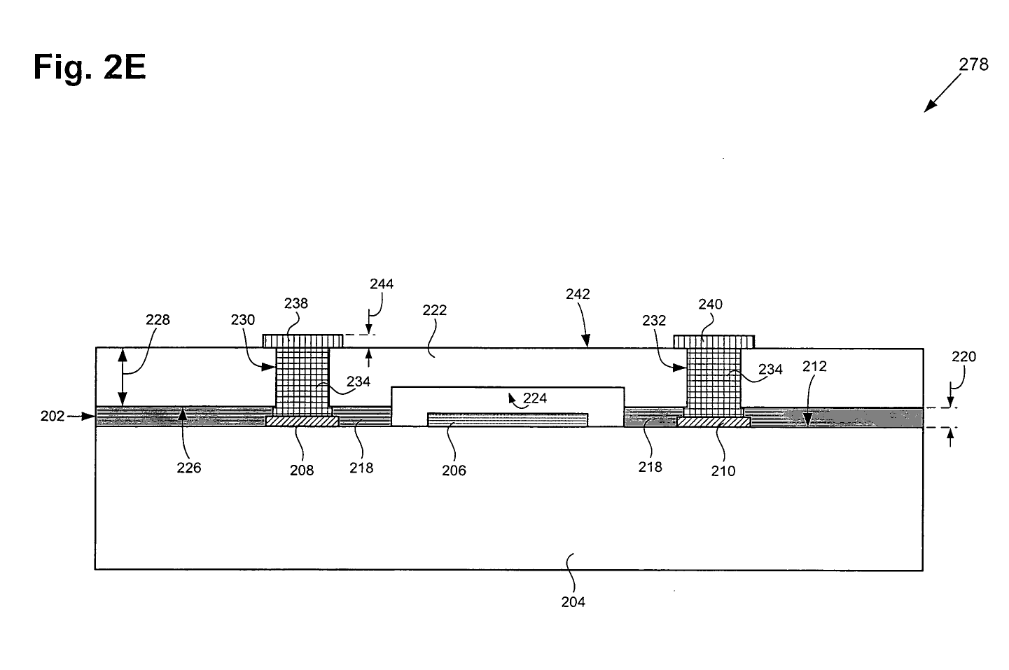

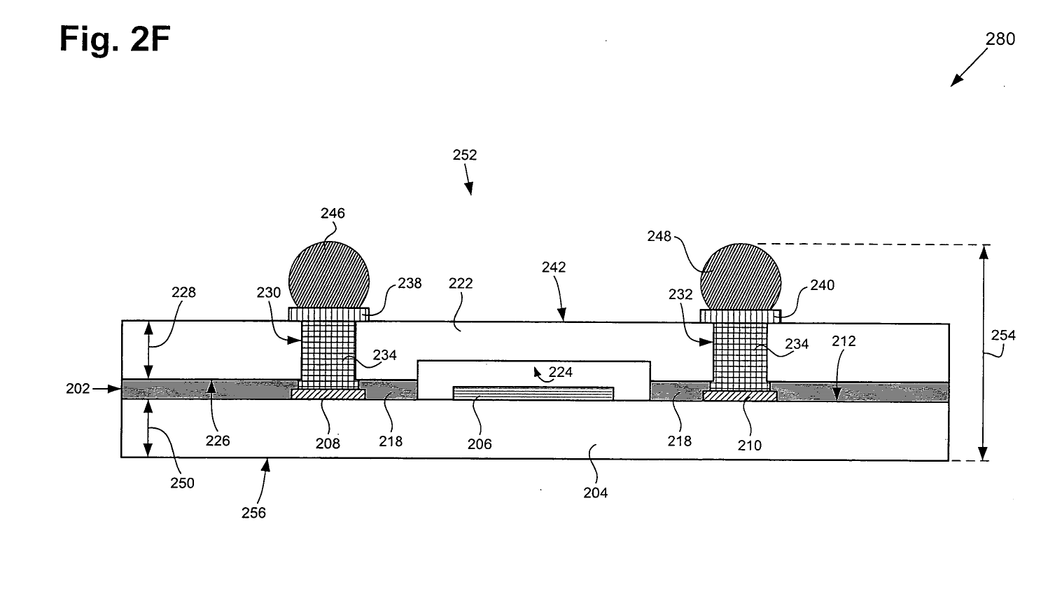

Moreover, structures 270 through 280 in FIGS. 2A through 2F illustrate the result of performing steps 170 through 180 of flowchart 100, respectively. For example, structure 270 shows a semiconductor structure after processing step 170, structure 272 shows structure 270 after the processing of step 172, structure 274 shows structure 272 after the processing of step 174, and so forth. It is noted that the processing steps shown in flowchart 100 are performed on a device wafer, which, prior to step 170, includes, for example, a device and two device wafer contacts.

Referring now to step 170 in FIG. 1 and structure 270 in FIG. 2A, at step 170 of flowchart 100, polymer layer 202 is formed on device wafer 204, which includes device 206 and device wafer contact pads 208 and 210. Device 206, which can comprise an IC, such as an RF (“Radio Frequency”) IC, is situated on device wafer 204, which can comprise silicon. In one embodiment, device 206 can comprise a MEMS device, such as an RF MEMS device. Device wafer contact pads 208 and 210 are situated on top surface 212 of device wafer 204 and are electrically connected to device 206. Device wafer contact pads 208 and 210 can comprise copper, aluminum, or other appropriate metal or metal alloy and can be formed on device wafer 204 in a manner known in the art. It is noted that although a device wafer including only one device and two device contact pads is specifically discussed herein to preserve brevity, the device wafer may include a large number of device contact pads and multiple devices.

Polymer layer 202 is situated on top surface 212 of device wafer 204 and includes openings 214 and 216, which are situated over respective device wafer contact pads 208 and 210. Polymer layer 202 forms a seal ring, which surrounds device 206. Polymer layer 202 can comprise a photoimageable polymer, such as benzocyclobutene (BCB), SU-8 (an epoxy-based negative resist), or one of the polyimide family of chemical structures. In one embodiment, polymer layer 202 may comprise a photoimageable epoxy. Polymer layer 202 has thickness 220, which may be, for example, between approximately 2.0 microns and approximately 50.0 microns.

Polymer layer 202 can be formed by applying a layer of polymer material on device wafer 204 by using a spin coating process, a spraying process, a screen printing process, or other appropriate process. The layer of polymer material is then patterned to form the seal ring, which surrounds and, thereby, protects device 206 from environmental contaminants. During the patterning and etching process, openings 214 and 216 are also formed in the layer of polymer material and over respective device wafer contact pads 208 and 210. The result of step 170 of flowchart 100 is illustrated by structure 270 in FIG. 2A.

Referring to step 172 in FIG. 1 and structure 272 in FIG. 2B, at step 172 of flowchart 100, cavity 224 is formed in protective wafer 222 and protective wafer 222 is bonded to device wafer 204 such that cavity 224 is situated over device 206. Protective wafer 222, which can comprise silicon, is situated such that top surface 226 of protective wafer 222 is in contact with polymer layer 202 and includes cavity 224, which is situated over device 206. Cavity 224 can be formed by patterning an opening on top surface 224 of protective wafer 222 and utilizing an appropriate etch process to remove a sufficient amount of silicon in the opening to form a cavity having a desired depth. In one embodiment, cavity 224 is not formed in protective wafer 222.

Protective wafer 222 can be bonded to device wafer 204 by performing a bonding process which utilizes polymer layer 202 as a bonding layer. In the bonding process, protective wafer 222 and device wafer 204 are appropriately aligned and pressed together at a sufficient pressure and temperature to cause protective wafer 222 to bond to device wafer 204. By way of example, the bonding process may be performed at a temperature of between approximately 100.0° C. and approximately 500.0° C. By utilizing polymer layer 202 as a bonding layer to bond protective wafer 222 to device wafer 204, the present invention achieves a wafer level package having a reduced cost compared to a conventional wafer level package that utilizes a high-cost metal, such as gold, in a bonding layer. The result of step 172 of flowchart 100 is illustrated by structure 272 in FIG. 2B. In one embodiment, a polymer layer is formed on top surface 226 of protective wafer 222, which is patterned to have its openings match openings 214 and 216.

Referring to step 174 in FIG. 1 and structure 274 in FIG. 2C, at step 174 of flowchart 100, a thinning process is performed to achieve target thickness 228 of protective wafer 222. By way of example, target thickness 228 of protective wafer 222 can be between approximately 50.0 microns and approximately 200.0 microns. In the thinning process, target thickness 228 of protective wafer 222 can be achieved by removing a sufficient amount of silicon material from protective wafer 222. The thinning process can comprise, for example, a grinding process, a chemical mechanical polishing (CMP) process, an etching process, or other appropriate material removal process. The result of step 174 of flowchart 100 is illustrated by structure 274 in FIG. 2C.

Referring to step 176 in FIG. 1 and structure 276 in FIG. 2D, at step 176 of flowchart 100, vias 230 and 232 are formed in protective wafer 222 over respective device wafer contact pads 208 and 210 and vias 230 and 232 are filled with conductive layer 234. Vias 230 and 232, which extend through protective wafer 222, are situated over respective device wafer contact pads 208 and 210. Vias 230 and 232 can be formed by patterning via openings on protective wafer 222 and extending the via openings through protective wafer 222 by utilizing a reactive ion etch (RIE) process, a wet etch process, or other appropriate etch process. Vias 230 and 232 have diameter 236, which can be, for example, between approximately 10.0 microns and approximately 100.0 microns.

After vias 230 and 232 have been formed, adhesion, barrier, and seed layers, which are not shown in FIG. 2D, may be deposited on the sidewalls of vias 230 and 232 to improve adhesion and prevent undesirable diffusion of subsequently deposited electrically conductive material into protective wafer 222. Conductive layer 234 is situated in vias 230 and 232 and can comprise copper, nickel, a gold/tin alloy, solder or other appropriate metal or metal alloy. Conductive layer 234, which is an electrically conductive layer, can be formed in vias 230 and 232 by utilizing an electroless plating process, an electroplating process, a screen printing process, or other appropriate deposition process to fill vias 230 and 232 with conductive material. Thus, vias 230 and 232, which are filled by conductive layer 234, are electrically connected to device 206 by way of respective device wafer contact pads 208 and 210, which are in contact with conductive layer 234. The result of step 176 of flowchart 100 is illustrated by structure 276 in FIG. 2D.

Referring to step 178 in FIG. 1 and structure 278 in FIG. 2E, at step 178 of flowchart 100, protective wafer contact pads 238 and 240 are formed on exposed surface 242 of protective wafer 222 and over respective vias 230 and 232. Protective wafer contact pads 238 and 240 are situated over and in contact with conductive layer 234 in respective vias 230 and 232. Thus, protective wafer contact pads 238 and 240 are electrically connected to respective device wafer contact pads 208 and 210. Protective wafer contact pads 238 and 240 have thickness 244, which can be, for example, approximately 2.0 microns and approximately 20.0 microns. Protective wafer contact pads 238 and 240 can comprise a portion of an under bump metallization (UBM) layer, which can comprise chrome/gold, nickel/copper, titanium/copper, or other appropriate metals. In one embodiment, protective wafer contact pads 238 and 240 are re-distributed to locations not directly situated over conductive layer 234.

Protective wafer contact pads 238 and 240 can be formed by depositing the UBM layer over vias 230 and 232 and on exposed surface 242 of protective wafer 222 by using a physical vapor deposition (PVD) process or other appropriate deposition process and appropriately patterning and etching the UBM layer. In one embodiment, land grid array (LGA) pads can be formed on exposed surface 242 of protective wafer 222 and over vias 230 and 232 in place of protective wafer contact pads 238 and 240. In such embodiment, the LGA pads can be used for surface mounting the wafer level package, which includes protective wafer 222 and device wafer 204, to a printed circuit board. The result of step 178 of flowchart 100 is illustrated by structure 278 in FIG. 2E.

Referring to step 180 in FIG. 1 and structure 280 in FIG. 2F, at step 180 of flowchart 100, solder bumps 246 and 248 are formed on respective protective wafer contacts 238 and 240 and target thickness 250 of device wafer 204 is achieved by performing a thinning process. Solder bumps 246 and 248 are situated on respective protective wafer contact pads 238 and 240 and can comprise an appropriate solder material. Solder bumps 246 and 248 are electrically connected to device wafer contact pads 208 and 210 through vias 230 and 232 and protective wafer contact pads 238 and 240, respectively. Thus, since device wafer contact pads 208 and 210 are electrically connected to device 206, solder bumps 246 and 248 can provide electrical connectivity between device 206 and components external to the wafer level package (i.e. wafer level package 252) which houses device 206. In other embodiments, LGA pads or bond pads can be used in place of solder bumps 246 and 248 to electrically connect device 206 to components external to wafer level package 252. Thus, by forming solder bumps or LGA pads over vias, which are formed in a protective wafer and filled with a conductive layer, the present invention advantageously provides electrical connectivity between a device on a device wafer and components external to the invention's wafer level package without requiring bonding wires.

Target thickness 250 of device wafer 204 can be achieved by performing a thinning process to remove a sufficient amount of silicon material from device wafer 204. By way of example, target thickness 250 of device wafer 204 can be between approximately 50.0 microns and approximately 200.0 microns. The thinning process can be, for example, a grinding process, a CMP process, an etching process, or other appropriate process. As shown in FIG. 2F, wafer level package 252 has thickness 254, which corresponds to the distance between bottom surface 256 of device wafer 204 and the tops of solder bumps 246 and 248. By way of example, thickness 254 can be between approximately 100.0 microns and approximately 800.0 microns. In one embodiment, thickness 254 may be between approximately 350.0 microns and approximately 600.0 microns. The result of step 180 of flowchart 100 is illustrated by structure 280 in FIG. 2F.

Thus, as discussed above, the present invention achieves a wafer level package including a protective wafer bonded to a device wafer, where vias extending through the protective wafer are filled with a conductive material to provide electrical connectivity between protective wafer contact pads and device wafer contact pads. By forming solder bumps or LGA pads over the vias on the protective wafer, the present invention advantageous provides electrical connectivity between a device on the device wafer and components external to the wafer level package without requiring bonding wires. As a result, the present invention advantageously achieves a wafer level package having a smaller footprint than a conventional wafer level package that requires space-consuming bonding wires to achieve connectivity with external components.

Also, as discussed above, in the present invention's wafer level package, a polymer layer is utilized as a bonding layer to bond a protective wafer to a device wafer. As a result, the present invention's wafer level package advantageously achieves a lower package cost than a conventional wafer level package that utilizes a costly metal or metal alloy such as gold or gold-tin to form a bonding layer between two wafers.

From the above description of the invention it is manifest that various techniques can be used for implementing the concepts of the present invention without departing from its scope. Moreover, while the invention has been described with specific reference to certain embodiments, a person of ordinary skill in the art would appreciate that changes can be made in form and detail without departing from the spirit and the scope of the invention. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

Thus, method for fabricating wafer level package having through wafer vias for external package connectivity and related structure have been described.

1. A method for fabricating a wafer level package, said method comprising:
forming a polymer layer on a device wafer, said device wafer comprising at least one device wafer contact pad and at least one device, said at least one device wafer contact pad being electrically connected to said at least one device;
bonding a protective wafer to said device wafer;
forming at least one via in said protective wafer, said at least one via extending through said protective wafer;
wherein said at least one via is situated over said at least one device wafer contact pad.

2. The method of claim 1 further comprising a step of forming at least one opening and a seal ring in said polymer layer prior to said step of bonding said protective wafer to said device wafer, wherein said at least one opening is situated over said at least one device wafer contact pad and said seal ring surrounds said at least one device.

3. The method of claim 1 further comprising a step of filling said at least one via with a conductive layer, wherein said conductive layer is in contact with said at least one device wafer contact pad.

4. The method of claim 1 further comprising a step of forming at least one protective wafer contact pad on said protective wafer, wherein said at least one protective wafer contact pad is situated over said at least one via and electrically connected to said at least one device wafer contact pad.

5. The method of claim 4 further comprising a step of forming at least one solder bump on said at least one protective wafer contact pad.

6. The method of claim 1 further comprising a step of performing a thinning process to achieve a target thickness of said protective wafer prior to said step of forming said at least one via in said protective wafer.

7. The method of claim 1 further comprising a step of performing a thinning process to achieve a target thickness of said device wafer.

8. The method of claim 1 further comprising a step of forming a cavity in said protective wafer prior to said step of bonding said protective wafer to said device wafer.

9. The method of claim 1 wherein said at least one via has a diameter of between approximately 10.0 microns and approximately 100.0 microns.

10. The method of claim 1 wherein said polymer layer comprises a photoimageable polymer.

11-20. (canceled)

21. A method for fabricating a wafer level package, said method comprising:
forming a polymer layer on a device wafer, said device wafer comprising at least one device wafer contact pad and at least one device, said at least one device wafer contact pad being electrically connected to said at least one device;
forming a seal ring and at least one opening in said polymer layer, said seal ring surrounding said at least one device and said at least one opening being situated over said at least one device wafer contact pad;
bonding a protective wafer to said device wafer in a bonding process;
wherein said bonding process utilizes said polymer layer as a bonding layer.

22. The method of claim 21 further comprising a step of forming at least one via in said protective wafer, wherein said at least one via extends through said protective wafer and is situated over said at least one device wafer contact pad.

23. The method of claim 22 further comprising a step of filling said at least one via with a conductive layer, wherein said conductive layer is in contact with said at least one device wafer contact pad.

24. The method of claim 22 further comprising a step of forming at least one protective wafer contact pad on said protective wafer, wherein said at least one protective wafer contact pad is situated over said at least one via and electrically connected to said at least one device wafer contact pad.

25. The method of claim 21 further comprising a step of performing a thinning process to achieve a target thickness of said protective wafer.

26. The method of claim 22 further comprising a step of performing a thinning process to achieve a target thickness of said device wafer.

27. The method of claim 21 further comprising a step of forming a cavity in said protective wafer prior to said step of bonding said protective wafer to said device wafer.

28. The method of claim 21 wherein said bonding process is performed at a temperature of between approximately 100.0° C. and approximately 500.0° C.

29. The method of claim 22 wherein said at least one via has a diameter of between approximately 10.0 microns and approximately 100.0 microns.

30. The method of claim 21 wherein said polymer layer comprises a photoimageable polymer.
